(19) United States
(12) Patent Application Publication
(10) Pub. No.: US 2024/0247155 A1
(43) Pub. Date: Jul. 25, 2024

(54) QUANTUM DOT FILM MANUFACTURING METHOD AND DEVICE, PHOTOELECTRIC DEVICE USING THE SAME

(71) Applicant: University-Industry Cooperation Group of Kyung Hee University, Yongin-Si (KR)

(72) Inventors: Seong Jun Kang, Seoul (KR); Min Gye Kim, Suwon-Si (KR)

(73) Assignee: University-Industry Cooperation Group of Kyung Hee University, Yongin-Si (KR)

(21) Appl. No.: 18/422,806

(22) Filed: Jan. 25, 2024

(30) Foreign Application Priority Data
Jan. 25, 2023 (KR) 10-2023-0009317

(51) Int. Cl. C09D 5/22; C09K 11/02; C09K 11/56; C09K 11/88; H01L 31/0352

(52) U.S. Cl. CPC C09D 5/22; C09K 11/025; C09K 11/565; C09K 11/883; H01L 31/035218

(57) ABSTRACT

The present disclosure relates to a method and device for manufacturing a core/shell-based quantum dot film having a desired thickness using a spray coating technique. The manufacturing method according to the present disclosure includes a first process for spray coating a quantum dot solution on a substrate to form a quantum dot film of a monolayer thin film of a predetermined thickness and a second process for performing a heat treatment at a predetermined temperature to desorb surface ligands present in the quantum dot film spray-coated by the first process. The spray coating condition for the first process includes spraying, by the spray gun, the quantum dot solution through a nozzle at a gas pressure of 0.4 kg/cm² (5.7 psi) and coating the quantum dot solution on the substrate while a moving stage moves at a speed of 0.012 m/s, a diameter of the nozzle is 0.3 mm, and a distance between the nozzle and the substrate is 10 cm. A temperature of the heat treatment of the second process is 90° C.

### CROSS-REFERENCE TO RELATED APPLICATION

This application claims the benefit under 35 U.S.C. § 119 of Korean Patent Application No. 10-2023-0009317 filed on Jan. 25, 2023, in the Korean Intellectual Property Office, the entire disclosure of which is incorporated herein by reference for all purposes.

### BACKGROUND

### 1. Field

The present disclosure relates to a method of manufacturing a quantum dot film based on core/shell structures to achieve a desired thickness using spray coating technique, quantum dot films manufactured by the manufacturing method, and a photoelectric device using them.

### 2. Description of Related Art

Quantum dots are nanoparticles of tens of nanometers or less in size with semiconductor properties, whose emission wavelength can be adjusted according to the size of the crystal particles, and can be fabricated through a simple solution process. These properties have been widely used in recent years to manufacture photoelectric devices such as solar cells.

In photoelectric devices and others, quantum dots are used as active layers. Therefore, the thickness of the quantum dots can affect the performance and efficiency of the device, and to ensure optimal performance, it is necessary to form the thickness of quantum dots appropriately and uniformly.

In the conventional method for producing quantum dots, there is a solution process. The solution process offers the advantage of relatively lower cost compared to vacuum deposition methods for forming quantum dot thin films. In conventional devices for manufacturing a quantum dot-based solar cell, coating or printing quantum dots to form a quantum dot solution layer has been disclosed in Prior Art 1 (Korean Patent No. 10-1525469, May 28, 2015).

However, quantum dots with shells and ligands applied to protect the core of the quantum dots encounters an issue where the ligands present on the surface of the quantum dots can protect the quantum dots in liquid form, but in film form, they undermine uniformity. Additionally, in solution processes, forming quantum dots in a multi-layer structure is necessary to achieve the desired thickness, but this leads to difficulty in finely adjusting the thickness due to solvent dissolution of the underlying layers by the upper layer solvent.

### SUMMARY

In one general aspect, a method for manufacturing a quantum dot film includes: a first process of spray coating a quantum dot solution on a substrate to form a quantum dot film of a single thin film with a predetermined thickness; and a second process of performing a heat treatment at a predetermined temperature to desorb surface ligands present in the quantum dot film spray-coated by the first process.

The first process and the second process may be repeatedly performed to form a quantum dot film of a desired thickness.

The conditions for the spray coating of the first process may include spraying, by the spray gun, the quantum dot solution through a nozzle at a gas pressure of 0.4 kg/cm² (5.7 psi) and coating the quantum dot solution on the substrate while a moving stage moves at a speed of 0.012 m/s.

A diameter of the nozzle may be 0.3 mm, and a distance between the nozzle and the substrate may be 10 cm.

The first process may be performed only three times, where a non-radiative recombination lifetime is the lowest.

A temperature of the heat treatment of the second process may be 90° C.

The quantum dot film may have a core/shell structure based on CdSe/ZnS. The quantum dot solution may be based on toluene as a solvent.

The quantum dot film manufactured by the first process and the second process may exhibit identical ratios of absorption and thickness according to a number of spray coating repetitions.

In another aspect, a quantum dot film manufacturing device includes: a spray coating unit comprising a moving stage on which a substrate is mounted on an upper surface and which moves at a predetermined speed by a driving force, and a spray gun equipped with a nozzle for spraying a quantum dot solution on the substrate; and a heat treatment unit for performing heat treating to desorb surface ligands of the quantum dot film spray-coated on the substrate by the spraying of the quantum dot solution.

In the spray coating unit, a moving speed of the moving stage may be 0.012 m/s, a distance between the nozzle and the substrate may be 10 cm, a diameter of the nozzle may be 0.3 mm, and a gas pressure of the spray gun may be 0.4 kg/cm² (5.7 psi). A temperature of the heat treatment in the heat treatment unit may be 90° C.

The quantum dot film may have a core/shell structure based on CdSe/ZnS. The quantum dot solution may be based on toluene as a solvent.

The number of spray coating repetitions by the spray coating unit may be determined to be only three, which has a lowest non-radiative recombination lifetime.

In another aspect, a photoelectric device is by the aforementioned quantum dot film manufacturing device.

### BRIEF DESCRIPTION OF THE DRAWINGS

FIG. 1 illustrates the configuration of a quantum dot film manufacturing device according to a preferred embodiment of the present disclosure.

FIG. 2 illustrates a diagram showing the surface characteristics of a quantum dot film according to different temperatures of a heat treatment process.

FIG. 3 illustrates a process diagram for manufacturing a quantum dot film using the quantum dot film manufacturing device of the present disclosure.

FIG. 4 illustrates an FE-SEM image capturing the surface morphology and crystal structure of a quantum dot film according to the number of spray coating repetitions.

FIG. 5 illustrates a diagram showing the patterned state of a quantum dot film of the present disclosure on a substrate.

FIG. 6 illustrates a graph showing the ratios of absorbance and thickness of a quantum dot film according to the number of spray coating repetitions in accordance with the present disclosure.

### DETAILED DESCRIPTION

This invention is capable of various modifications and can have several embodiments, therefore, specific embodiments are illustrated in the drawings and described in detail. However, this is not intended to limit the invention to any particular embodiment, and is to be understood to include all modifications, equivalents or substitutions that fall within the scope of the thought and skill of the present disclosure. In describing the invention, where it is believed that a detailed description of the relevant prior art would obscure the gist of the invention, such detailed description is omitted.

Terms such as first, second, and the like may be used to describe various components, but the components shall not be limited by such terms. These terms are used only for the purpose of distinguishing one component from another.

The terminology used in the present disclosure is intended to describe particular embodiments only and is not intended to limit the invention. Expressions in the singular include the plural unless the context clearly indicates otherwise. In this application, terms such as “includes” or “has” are intended to designate the presence of the features, numbers, steps, actions, components, parts, or combinations thereof described in the specification, not the presence of one or more other features, numbers, steps, actions, components, or combinations thereof.

The spatially relative terms below, beneath, lower, above, upper, and the like may be used to facilitate the description of the relationship of one element or component to another element or component as shown in the drawings. Spatially relative terms should be understood to include different orientations of an element in use or operation in addition to the orientations shown in the drawings. For example, an element described as being below or beneath another element may be placed above or above another element when the elements shown in the drawing are inverted. Thus, the exemplary term below may include both below and above orientations. Elements may also be orientated in other directions, and accordingly, spatially relative terms may be interpreted according to their orientation.

Accordingly, the idea of the invention is not to be limited to the embodiments described, and it will be understood that the following patent claims, as well as all equivalents or equivalent variations thereof, fall within the scope of the idea of the invention.

The object of the present disclosure is to solve the above problems. The present disclosure provides a method for manufacturing a quantum dot film having a uniform thin film with a desired thickness.

Another object of the present disclosure is to provide spray coating technique optimized for quantum dot luminescent materials, enabling the manufacture of a quantum dot film with a uniform thin film thickness.

Another object of the present disclosure is to provide a photoelectric device manufactured by applying a quantum dot film with a uniform thickness.

Hereinafter, the present disclosure will be described in more detail based on the embodiments shown in the drawings.

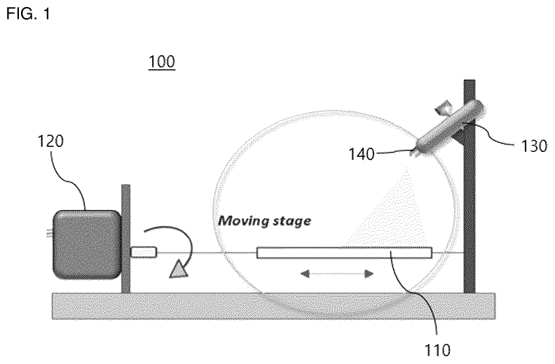

FIG. 1 illustrates the configuration of a quantum dot film manufacturing device according to a preferred embodiment of the present disclosure. The quantum dots produced by a quantum dot film manufacturing device 100 according to the present disclosure may, for example, be core/shell structured quantum dots based on CdSe/ZnS. Core/shell structured quantum dots based on CdSe/ZnS are semiconductor particles commonly used as the active layer in photoelectric devices. Through the formation of high-quality thin films, improved device characteristics utilizing quantum dots in photoelectric devices can be expected. Hereinafter, core/shell structured quantum dots based on CdSe/ZnS will be simply referred to as CdSe/ZnS quantum dots or quantum dots for ease of explanation.

As shown in FIG. 1, a quantum dot film manufacturing device 100 according to the present disclosure includes a spray coating unit and a heat treatment unit to manufacture a CdSe/ZnS quantum dot film.

In FIG. 1, a spray coating unit includes a substrate (not shown) for applying a spray coating technique, a moving stage (110) on which the substrate is mounted and which moves in a left-to-right direction, a drive means 120 providing a driving force to move the moving stage 110 at a predetermined speed, and a spray gun 130 equipped with a nozzle 140 for spraying quantum dot solution (e.g., toluene solvent-based) to coat quantum dot film on the moving substrate.

The substrate may be a substrate of a flexible and elastic material such as polydimethylsiloxane (PDMS), and through the spray coating process, a quantum dot film with a desired thickness can be formed on the substrate. Furthermore, it is possible to form the film into specific patterns.

The moving stage 110 may be provided with fixing means (not shown), etc., to maintain a fixed posture without movement during the spray coating process while the substrate is held. Furthermore, the moving stage 110 is connected to a drive shaft of the drive means 120 by shafts, etc., and is driven to reciprocate left and right based on the drawing by the driving force. The drive means 120 may be a motor or similar things providing the driving force.

The spray gun 130 is installed on the upper surface of the substrate to spray quantum dot solution to coat it on the substrate. The installation site may be positioned either centrally at the top of the substrate or slightly positioned toward to the left or right sides.

According to one or more embodiments of the present disclosure, the spray coating technique for forming a quantum dot film using the spray gun 130 can be determined by various variables, such as the diameter of the nozzle 140, the Nozzle to Substrate Distance (NSD), and the substrate's moving speed. The embodiments of the present disclosure present the following conditions for forming a quantum dot film using optimized spray coating technique. These conditions may be optimized process conditions obtained through a large number of repeated experiments. With the above process conditions, the moving speed of the moving stage 110 is set to 0.012 m/s, the NSD is set to 10 cm, the nozzle size of the spray gun 130 is set to 0.3 mm, and the gas pressure of the spray gun 140 is set to 0.4 kg/cm² (5.7 psi).

The number of spray coating using the spray coating unit will be determined to ensure that the quantum dot film has a predetermined thickness depending on the characteristics of a photoelectric device to be manufactured to which the quantum dot film is applied.

Although the heat treatment unit is not shown in FIG. 1, it is configured to perform heat treatment at a predetermined temperature to reduce the influence of ligands present on the surface of the quantum dot film manufactured by the spray coating unit. The reason for using the heat treatment process by the heat treatment unit is that washing with a solvent to remove ligands may cause particle aggregation of the quantum dots.

Specifically, an alkyl chain of 1-dodecanethiol (1-DDT) exist on the surface of the quantum dots, and it is necessary to adjust the amount of ligands in order to uniformly form a monolayer according to the number of coatings. This adjustment has traditionally been achieved through processes such as ligand exchange, but such ligand exchange present challenges due to the complexity of the process. For example, a process of exchanging ligands with shorter alkyl chains was required to remove excessive surface ligands or enhance the mobility of charge carriers.

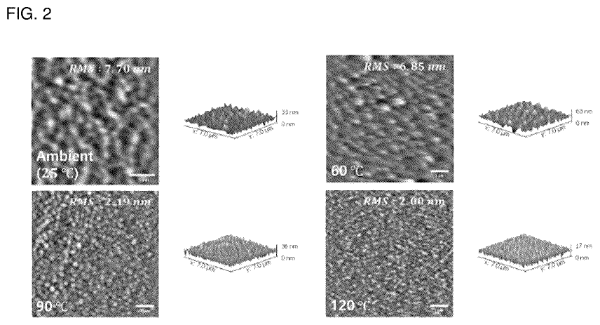

However, in embodiments of the present disclosure, the C12 alkyl chains present on the surface of the quantum dots can be desorbed to form a quantum dot monolayer without the need for complicated processes such as the aforementioned ligand exchange. The ligand desorption is carried out through optimized heat treatment conditions. In embodiments, the heat treatment temperature during the heat treatment process is determined to be 90° C. The reason for setting the heat treatment temperature at 90° C. is referenced to FIG. 2.

FIG. 2 illustrates a diagram showing the surface characteristics of a quantum dot film according to different temperatures of a heat treatment process. The surface of the quantum dot film was analyzed using the Atomic Force Microscopy (AFM) method.

As illustrated in FIG. 2, experimental results of setting the heat treatment temperature to 25° C., 60° C., 90° C., and 120° C. showed that the relatively higher heat treatment temperatures affected the surface of a monolayer of the quantum dot film, while decreasing heat treatment temperatures result in an increase in the roughness of the monolayer surface of the quantum dot film.

In other words, it was confirmed that after the surface roughness of the quantum dot film decreased when the heat treatment temperature was set to 90° C., there was no significant difference observed at 120° C. Therefore, the temperature of the heat treatment process in this embodiment of the present disclosure was set to 90° C.

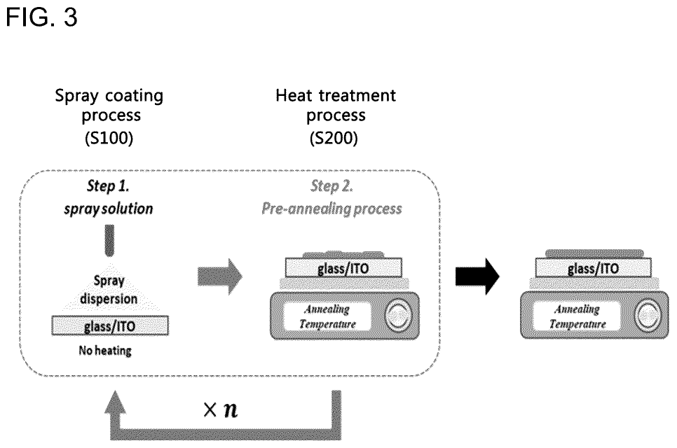

FIG. 3 illustrates a process diagram for manufacturing a quantum dot film using the quantum dot film manufacturing device of the present disclosure.

As shown in FIG. 3, the manufacturing process includes a spray coating process (S100) and a heat treatment process (S200), which are conducted sequentially. These processes (S100, S200) may be repeated multiple times depending on the thickness of the quantum dot film.

The spray coating process (S100) is carried out according to the optimized spray coating conditions mentioned earlier. When a moving stage 110 moves at a speed of 0.012 m/s by a drive means 120, a nozzle 140 of a spray gun sprays the quantum dot solution at a relatively low gas pressure of 0.4 kg/cm² (5.7 psi), coating the substrate on the moving stage 110 with a predetermined thickness. Through the spray coating technique, a quantum dot monolayer is formed in a single spray coating process.

After the formation of the quantum dot monolayer through the spray coating process S100, a heat treatment process S200 is conducted to detach the alkyl chains in order to adjust the ligand amount. The heat treatment process S200 is conducted in a 90° C. atmosphere, inducing the loss of ligands from the quantum dot surface without damaging the quantum dots to form a uniform quantum dot surface.

In the embodiments of the present disclosure, the spray coating process S100 and the heat treatment process S200 may be repeatedly conducted multiple times to manufacture a quantum dot film of a desired thickness. Through this entire process, it is possible to manufacture a quantum dot film with a desired thickness and a uniform film morphology on the substrate. Moreover, through the loss of surface ligands, it is possible to form a uniform quantum dot film of any desired thickness, ranging from a monolayer film to a multi-layer film. Due to the adjustability of monolayer film thickness, it is possible to manufacture various photoelectric devices with optimized characteristics for different thicknesses.

According to the embodiments of the present disclosure, it can be confirmed that the fluorescence lifetime of the quantum dot film is dependent on the radiative recombination (RR, R_{R}) of excitons, through measurements from a fluorescence lifetime measuring device (e.g., a time-resolved photoluminescence device). Grazing incidence X-Ray diffraction (GIXRD) measurements suggest that this dependency may be a consequence of the asymmetric hexagonal core crystal structure. Another factor that determines the fluorescence lifetime of the quantum dot film is related to non-radiative recombination (PNR, R_{NR}).

It is important to suppress non-radiative recombination because it degrades the luminescence performance of light emitting devices (e.g., light emitting diodes). According to embodiments of the present disclosure, when the spray coating process S100 is repeated three times, the non-radiative recombination lifetime is observed to be the lowest (refer to Table 1 below). Therefore, applying the quantum dot film manufactured by three repetitions of the spray coating process in accordance with the present disclosure to a light emitting diode would yield the best device performance. Table 1 illustrates the status of non-radiative recombination according to the number of spray coating repetitions.

TABLE 1

| | [symbol] _{decay average} | [symbol] _{R} | [symbol] _{NR} | R_{R} | R_{NR} |
|---|---|---|---|---|---|
| Samples | (ns) | (ns) | (ns) | (ns⁻¹) | (ns⁻¹) |
| S [symbol] -QD [symbol] × 1 | 15.8 | 21.1 | 13.3 | 0.047 | 0.075 |
| S [symbol] -QD [symbol] × 2 | 17.4 | 28.2 | 14.0 | 0.035 | 0.072 |
| S [symbol] -QD [symbol] × 3 | 16.6 | 26.7 | 14.3 | 0.037 | 0.070 |
| S [symbol] -QD [symbol] × 4 | 15.5 | 24.7 | 13.9 | 0.040 | 0.072 |
| S [symbol] -QD [symbol] × 5 | 18.1 | 21.3 | 13.9 | 0.047 | 0.072 |

[symbol]

indicates data missing or illegible when filed

Next, the surface morphology and crystal structure of the quantum dot film according to the present disclosure will be discussed.

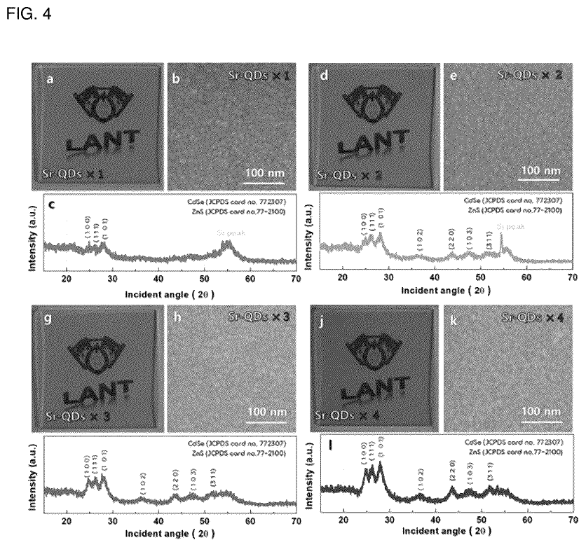

FIG. 4 illustrates an FE-SEM image capturing the surface morphology and crystal structure of a quantum dot film according to the number of spray coating repetitions.

In (a), (d), (g), and (j) of FIG. 4, it can be seen that the rapid evaporation of the solvent, toluene, leads to a reduction in the aggregation of the quantum dot film and thus fluorescent light appears uniformly across all samples where different numbers of spray coating processes are applied. Additionally, in (b), (e), (h), and (k) of FIG. 4, a uniform and pinhole-free monolayer surface can be observed.

It can be seen that the results of FIG. 4 are attributed to the optimized spray coating process S100 and heat treatment process S200, and especially, a uniform and pinhole-free surface was observed in all samples regardless of the number of spray coating repetitions.

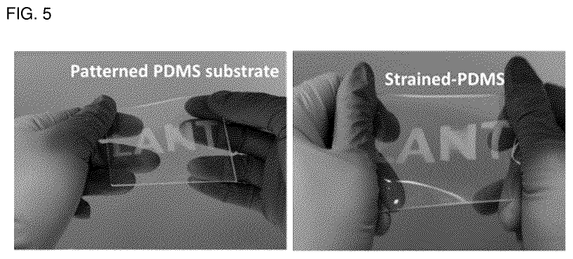

FIG. 5 illustrates a diagram showing the patterned state of a quantum dot film of the present disclosure on a substrate. The substrate in FIG. 5 is a flexible and elastic polydimethylsiloxane (PDMS) substrate, where a quantum dot film was spray-coated and patterned.

Upon observation, it can be confirmed that compared to the patterned PDMS substrate before strain, the spray-coated pattern remains stable and distinct even when stretched or twisted. This demonstrates that it is easier to coat the desired patterns using a pattern mask on various substrates compared to conventional solution processes.

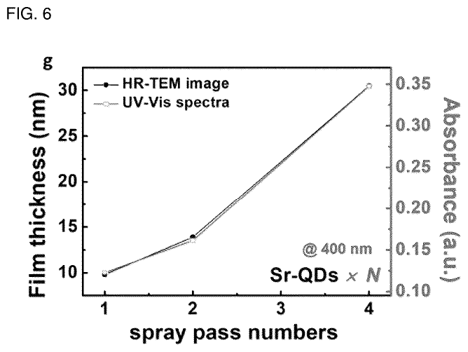

FIG. 6 illustrates a graph showing the ratios of absorbance and thickness of a quantum dot film according to the number of spray coating repetitions in accordance with the present disclosure.

In FIG. 6, it can be seen that the ratios of absorbance and thickness are consistent, which means that the quantum dot thin film is uniformly stacked by the spray coating process for film formation and the heat treatment process for ligand removal.

As described above, it can be confirmed that the present disclosure uses a spray coating technique based on a solution process instead of conventional spin-coating methods to form a uniform and pinhole-free quantum dot fil, and that by controlling the thickness of the quantum dot film, various photoelectric devices with optimized device characteristics by thickness can be manufactured.

The photoelectric device according to the present disclosure can be applied across various technical fields. For example, it can be extensively applied to LED display devices, photodiode devices, quantum dot-based solar cell devices, etc., employing flexible materials based on quantum dots, and thus has great industrial applicability.

According to the present disclosure, through a spray coating process optimized for quantum dot light emitting materials and low-temperature heat treatment process minimizing damage to the quantum dot film surface, it is possible to induce loss of surface ligands on quantum dots, thereby forming a uniform quantum dot film of the desired thickness.

According to the present disclosure, it is possible to adjust the thickness of the quantum dots used as an active layer in a photoelectric device, thereby expecting an improvement in the performance of the photoelectric device.

As described above, the present disclosure is described with reference to the illustrated embodiments, but these are merely illustrative examples, and those of ordinary skill in the art to which the present disclosure pertains can make various modifications without departing from the gist and scope of the present disclosure. It will be apparent that variations, modifications, and equivalent other embodiments are possible. Therefore, the true scope of technical protection of the present disclosure should be determined by the technical sprit of the appended claims.

1. A method for manufacturing a quantum dot film, comprising:
a first process of spray coating a quantum dot solution on a substrate to form a quantum dot film of a single thin film with a predetermined thickness; and
a second process of performing a heat treatment at a predetermined temperature to desorb surface ligands present in the quantum dot film spray-coated by the first process.

2. The method of claim 1,
wherein the first process and the second process are repeatedly performed to form a quantum dot film of a desired thickness.

3. The method of claim 1,
wherein conditions for the spray coating of the first process comprise spraying, by the spray gun, the quantum dot solution through a nozzle at a gas pressure of 0.4 kg/cm² (5.7 psi) and coating the quantum dot solution on the substrate while a moving stage moves at a speed of 0.012 m/s.

4. The method of claim 3,
wherein a diameter of the nozzle is 0.3 mm, and a distance between the nozzle and the substrate is 10 cm.

5. The method of claim 1,
wherein the first process is performed only three times, where a non-radiative recombination lifetime is the lowest.

6. The method of claim 1,
wherein a temperature of the heat treatment of the second process is 90° C.

7. The method of claim 1,
wherein the quantum dot film has a core/shell structure based on CdSe/ZnS, and
wherein the quantum dot solution is based on toluene as a solvent.

8. The method of claim 1,
wherein the quantum dot film manufactured by the first process and the second process exhibit identical ratios of absorption and thickness according to a number of spray coating repetitions.

9. A quantum dot film manufacturing device, comprising:
a spray coating unit comprising a moving stage on which a substrate is mounted on an upper surface and which moves at a predetermined speed by a driving force, and a spray gun equipped with a nozzle for spraying a quantum dot solution on the substrate; and
a heat treatment unit for performing heat treating to desorb surface ligands of the quantum dot film spray-coated on the substrate by the spraying of the quantum dot solution.

10. The device of claim 9,
wherein in the spray coating unit, a moving speed of the moving stage is 0.012 m/s, a distance between the nozzle and the substrate is 10 cm, a diameter of the nozzle is 0.3 mm, and a gas pressure of the spray gun is 0.4 kg/cm² (5.7 psi), and
wherein a temperature of the heat treatment in the heat treatment unit is 90° C.

11. The device of claim 9,
wherein the quantum dot film has a core/shell structure based on CdSe/ZnS, and
wherein the quantum dot solution is based on toluene as a solvent.

12. The device of claim 9,
wherein a number of spray coating repetitions by the spray coating unit is determined to be only three, which has a lowest non-radiative recombination lifetime.

13. A photoelectric device manufactured by a quantum dot film manufacturing device comprising the configuration of claim 9.

14. The device of claim 13,
wherein the photoelectric device comprises an LED display device based on flexible materials, a photodiode device based on flexible materials, and a solar cell device.
